(19) United States
(12) Patent Application Publication
(10) Pub. No.: US 2016/0167518 A1
(43) Pub. Date: Jun. 16, 2016

(54) POWER HEAT DISSIPATION DEVICE AND METHOD FOR CONTROLLING THE SAME

(71) Applicant: INDUSTRIAL TECHNOLOGY RESEARCH INSTITUTE, Hsinchu (TW)

(72) Inventors: Po-Hua CHANG, Nantou County (TW); Kou-Tzeng LIN, Hsinchu County (TW); Chih-Yu HWANG, Taoyuan City (TW); Min-Chuan WU, Taipei City (TW); Wen-Shu CHIANG, Hsinchu City (TW)

(73) Assignee: INDUSTRIAL TECHNOLOGY RESEARCH INSTITUTE, Hsinchu (TW)

(21) Appl. No.: 14/919,237

(22) Filed: Oct. 21, 2015

(30) Foreign Application Priority Data
Dec. 10, 2014 (TW) 103143064

(51) Int. Cl. B60L 1/12; H01L 35/30

(52) U.S. Cl. CPC B60L 1/12; H01L 35/30

(57) ABSTRACT

A power heat dissipation device includes a heat-conducting layer, a heat sink and at least one thermoelectric cooling chip. The heat-conducting layer has a heat-absorbing-surface and a heat-dissipating-surface which are opposite to each other. The heat sink is in thermal contact with the heat-dissipating-surface of the heat-conducting layer. The at least one thermoelectric cooling chip is embedded in the heat-conducting layer. The heat-conducting layer has an effective heat-conducting-region. A1 is the area on the heat-absorbing-surface which the effective heat-conducting-region projects on, and A2 is the area on the heat-absorbing-surface which the thermoelectric cooling chip projects on. The ratio of A2 to A1 is between 0.15 and 0.58.

### CROSS-REFERENCE TO RELATED APPLICATIONS

This non-provisional application claims priority under 35 U.S.C. §119(a) on Patent Application No(s). 103143064 filed in Taiwan, R.O.C. on Dec. 10, 2014, the entire contents of which are hereby incorporated by reference.

### BACKGROUND

In recent years, the drive system for electric vehicles with high output power and a compact size has been developed and applied on small vehicles. To fulfill the requirements mentioned above, a controller of the drive system with a high power density is needed.

### SUMMARY

According to one embodiment of the present disclosure, a power heat dissipation device includes a heat-conducting layer, a heat sink and at least one thermoelectric cooling chip. The heat-conducting layer has a heat-absorbing-surface and a heat-dissipating-surface which are opposite to each other. The heat sink is in thermal contact with the heat-dissipating-surface of the heat-conducting layer. The at least one thermoelectric cooling chip is embedded in the heat-conducting layer. The heat-conducting layer has an effective heat-conducting-region. A1 is the area on the heat-absorbing-surface which the effective heat-conducting-region projects on, and A2 is the area on the heat-absorbing-surface which the thermoelectric cooling chip projects on. The ratio of A2 to A1 is between 0.15 and 0.58.

According to another embodiment of the present disclosure, a power heat dissipation control method includes the following steps. An output current of a motor is obtained. A thermoelectric cooling chip is turned on when the output current is larger than a predetermined output current.

According to another embodiment of the present disclosure, a power heat dissipation control method includes the following steps. An output torque of a motor is obtained. A thermoelectric cooling chip is turned on when the output torque is larger than a predetermined output torque.

According to the other embodiment of the present disclosure, a power heat dissipation control method includes the following steps. An output power of a motor is obtained. A thermoelectric cooling chip is turned on when the output power is larger than a predetermined output power.

### BRIEF DESCRIPTION OF THE DRAWINGS

The present disclosure will become better understood from the detailed description given hereinbelow and the accompanying drawings which are given by way of illustration only and thus are not limitative of the present disclosure and wherein:

FIG. 1 is a cross-sectional view of a power heat dissipation device according to a first embodiment of the disclosure;

FIG. 2 is a top view of the power heat dissipation device illustrated in FIG. 1;

FIG. 3 is a cross-sectional view of a power heat dissipation device according to a second embodiment of the disclosure;

FIG. 4 is a cross-sectional view of a power heat dissipation device according to a third embodiment of the disclosure; and

FIG. 5 is a block diagram of a heat dissipation control system of a power heat dissipation device according to a fourth embodiment of the disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawings.

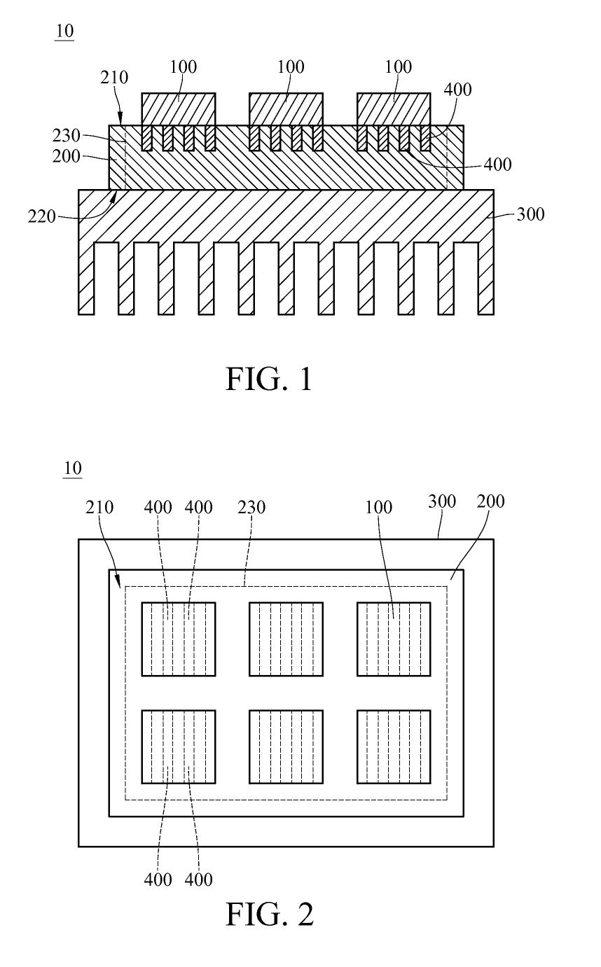

Please refer to FIG. 1 and FIG. 2. FIG. 1 is a cross-sectional view of a power heat dissipation device according to a first embodiment of the disclosure. FIG. 2 is a top view of the power heat dissipation device illustrated in FIG. 1.

In the first embodiment of the present disclosure, the power heat dissipation device 10 includes a heat-conducting layer 200, a heat sink 300 and a plurality of thermoelectric cooling chips 400.

A plurality of power elements 100 is disposed on the power heat dissipation device 10, and each of the power elements 100 has a heat transferring surface. The power element 100, for example, is a transistor. In addition, the power element 100, for example, has a maximum operating temperature when the power element 100 is under heavy load. When an operating temperature of the power element 100 is lower than the maximum operating temperature, the power element 100 has better functioning efficiency. In contrast, when the operating temperature of the power element 100 is higher than the maximum operating temperature, the functioning efficiency of the power element 100 decreases or even that the power element 100 crashes. Therefore, when the operating temperature of the power element 100 reaches the maximum operating temperature of the power element 100, it is necessary to execute a heat dissipation process for cooling down the power element 100 to the operating temperature being lower than the maximum operating temperature. The detail descriptions of the heat dissipation process are illustrated thereafter.

The heat-conducting layer 200, for example, is an aluminum substrate. The heat-conducting layer 200 has a heat-absorbing-surface 210 and a heat-dissipating-surface 220 which are opposite to each other. The heat-absorbing-surface 210 of the heat-conducting layer 200 is in thermal contact with the power element 100.

In addition, the heat-conducting layer 200 further has an effective heat-conducting-region 230. The effective heat-conducting-region 230 is a part of the heat-conducting layer 200 with a temperature higher than 35% of the maximum operating temperature of the power element 100. Specifically, each of the power elements 100 forms a part of the effective heat-conducting-region 230. A width and a length of each part of the effective heat-conducting-region 230 are three times larger than a width and a length of the power element 100, respectively. A central heat point of the power element 100 is located at a center point of a surface of the part of the effective heat-conducting-region 230 close to the power element 100. The heat released from the central heat points is transferred from the power elements 100 to the heat-conducting layer 200 so as to form the effective heat-conducting-region 230. A cross-sectional area of the effective heat-conducting-region 230 is proportional to an output power of the power element 100. In some other embodiments, there can be only one power element disposed on the power heat dissipation device 10, and the width and the length of total effective heat-conducting-region 230 is three times larger than the width and the length of the power element 100, respectively.

The heat sink 300, for example, is a plurality of cooling fin sets. The heat sink 300 is for dissipating the heat generated by the power elements 100, and the heat sink 300 is in thermal contact with the heat-dissipating-surface 220 within the effective heat-conducting-region 230 of the heat-conducting layer 200.

The thermoelectric cooling chips 400 are active cooling elements. The thermoelectric cooling chips 400 are embedded in the effective heat-conducting-region 230 of the heat-conducting layer 200 and directly in thermal contact with the power elements 100. The thermoelectric cooling chips 400 are attached to a part of the heat transferring surface of the power element 100 so that the power element 100 is in thermal contact with the heat-conducting layer 200 and the thermoelectric cooling chips 400, simultaneously. Therefore, when the thermoelectric cooling chips 400 are functioning, the power element 100 is rapidly cooled by the thermoelectric cooling chips 400 from the operating temperature over or equal to the maximum operating temperature to the operating temperature below the maximum operating temperature. When the thermoelectric cooling chips 400 are not functioning, the heat generated by the power element 100 is conducted by the heat-conducting layer 200 and then dissipated by the heat sink 300.

In addition, when cooling down the power element 100, the thermoelectric cooling chips 400 also generate heat and therefore the heat generated by the thermoelectric cooling chips 400 increases the burden of the heat sink 300. Furthermore, when the thermoelectric cooling chips 400 are not functioning, a heat conducting capability of each of the thermoelectric cooling chips 400 is much smaller than a heat conducting capability of the heat-conducting layer 200 so that a heat flow from the power element 100 to the thermoelectric cooling chips 400 decreases, thereby reducing the heat dissipation capability of power heat dissipation device 10.

As a result, in the first embodiment of the present disclosure shown in FIG. 2, let A1 be the area on the heat-absorbing-surface 210 which the effective heat-conducting-region 230 projects on, and let A2 be the area on the heat-absorbing-surface 210 which the thermoelectric cooling chip 400 projects on. The ratio of A2 to A1 is between 0.15 and 0.58. Therefore, the ratio of the areas mentioned above effectively avoids a reducing of the heat dissipation capability of the heat sink 300 caused by the thermoelectric cooling chips 400.

Furthermore, as shown in FIG. 2, the number of the thermoelectric cooling chip 400 is plural, and the number of the thermoelectric cooling chip 400 is proportional to the number of the power element 100. The thermoelectric cooling chips 400 are spaced apart from each other. At least a part of the orthogonal projection of the thermoelectric cooling chip 400 on the heat-absorbing-surface 210 is overlapped with a part of the orthogonal projection of the power element 100 on the heat-absorbing-surface 210. In the first embodiment of the present disclosure, each of the power elements 100 is arranged in a group with four thermoelectric cooling chips 400. However, the disclosure is not limited to the number of the thermoelectric cooling chips arranged in a group with each of the power elements. In other embodiments of the present disclosure, each of the power elements is arranged in a group with one thermoelectric cooling chip.

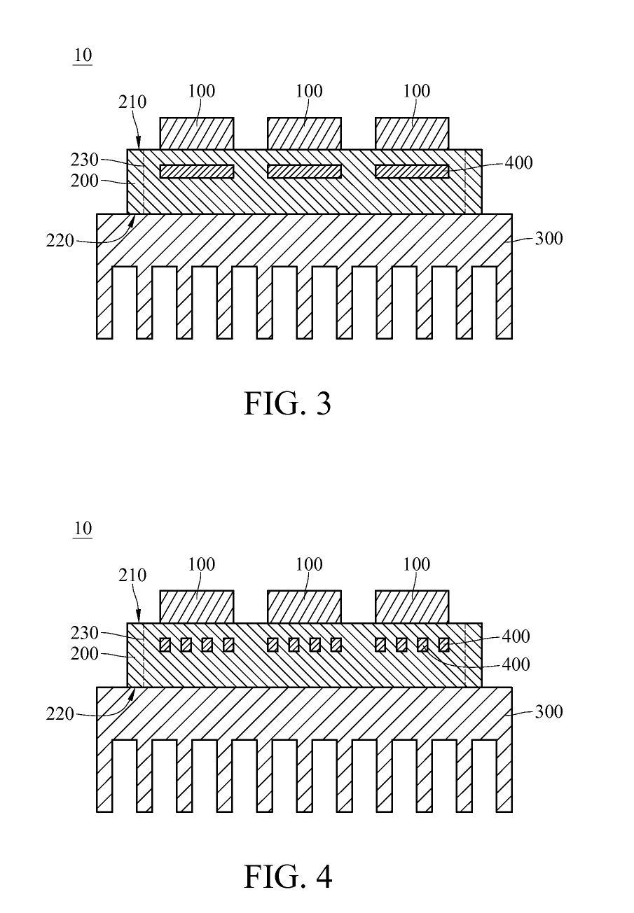

Please refer to FIG. 3. FIG. 3 is a cross-sectional view of a power heat dissipation device according to a second embodiment of the disclosure. The second embodiment of the present disclosure in FIG. 3 is similar to the first embodiment of the present disclosure. Therefore, the following descriptions focus on the difference between the first embodiment and the second embodiment.

In FIG. 3, each of the power elements 100 is arranged in a group with one thermoelectric cooling chip 400, and the thermoelectric cooling chip 400 is not in direct thermal contact with the power element 100. In detail, the power elements 100 are in thermal contact with the heat-absorbing-surface 210 of the heat-conducting layer 200, and the thermoelectric cooling chips 400 are spaced apart from the heat-absorbing-surface 210 of the heat-conducting layer 200. In other words, the thermoelectric cooling chips 400 keep a distance from the power elements 100.

Please refer to FIG. 4. FIG. 4 is a cross-sectional view of a power heat dissipation device according to a third embodiment of the disclosure. The third embodiment of the present disclosure in FIG. 4 is similar to the first embodiment of the present disclosure in FIG. 1 and FIG. 2. Therefore, the following descriptions focus on the difference between the first embodiment and the third embodiment.

In FIG. 4, each of the power elements 100 is arranged in group with four thermoelectric cooling chips 400, and each of the thermoelectric cooling chips 400 is not in direct thermal contact with the power element 100. In detail, the power elements 100 are in thermal contact with the heat-absorbing-surface 210 of the heat-conducting layer 200, and the thermoelectric cooling chips 400 are spaced apart from the heat-absorbing-surface 210 of the heat-conducting layer 200. In other words, the thermoelectric cooling chips 400 keep a distance from the power elements 100.

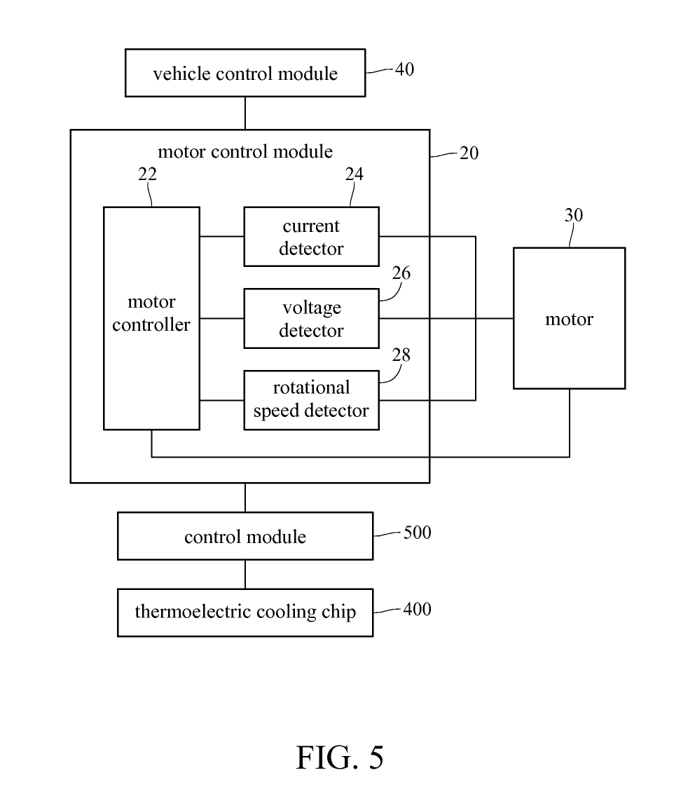

Please refer to FIG. 5. FIG. 5 is a block diagram of a heat dissipation control system of a power heat dissipation device according to a fourth embodiment of the disclosure. The heat dissipation control system can be applied to the power heat dissipation devices in the first embodiment to the third embodiment.

The on and off of the thermoelectric cooling chip 400 is controlled by a control module 500 of the thermoelectric cooling chip. The control module 500 of the thermoelectric cooling chip connects a motor control module 20 and a vehicle control module 40. The motor control module 20 includes a motor controller 22, a current detector 24, a voltage detector 26 and a rotational speed detector 28. The motor controller 22 controls a motor 30. The current detector 24, the voltage detector 26 and the rotational speed detector 28 detect a current, a voltage and a rotational speed of the motor 30, respectively. The vehicle control module 40 obtains a torque of the motor 30.

Three of the control methods of the power heat dissipation device 10 controlled by the heat dissipation control system are provided. In a first control method, whether the thermoelectric cooling chip 400 turns on or off is determined by the output power of the motor 30. In a first step of the first control method, the rotational speed and the torque of motor 30 are obtained by the rotational speed detector 28 and the vehicle control module 40, respectively. Next, an output power of the motor 30 which is derived from the rotational speed and the torque of the motor 30 by the control module 500 of the thermoelectric cooling chip 400 is obtained. Next, when the output power of the motor 30 is larger than a predetermined output power of the motor 30, the thermoelectric cooling chip 400 is turned on by the control module 500 to cool down the power element 100 to the operating temperature that is lower than the maximum operating temperature. Next, when the output power of the motor 30 is smaller than the predetermined output power of the motor 30, the thermoelectric cooling chip 400 is turned off by the control module 500.

In a second control method, whether the thermoelectric cooling chip 400 turns on or off is determined by the output current of the motor 30. In a first step of the second control method, the output current of motor 30 is obtained by the current detector 24. Next, when the output current of the motor 30 is larger than a predetermined output current of the motor 30, the thermoelectric cooling chip 400 is turned on by the control module 500 to cool down the power element 100 to the operating temperature lower than the maximum operating temperature. Next, when the output current of the motor 30 is smaller than the predetermined output power of the motor 30, the thermoelectric cooling chip 400 is turned off by the control module 500.

In a third control method, whether the thermoelectric cooling chip 400 turns on or off is determined by the output torque of the motor 30. In a first step of the third control method, the output torque of motor 30 is obtained by the vehicle control module 40. Next, when the output torque of the motor 30 is larger than a predetermined output torque of the motor 30, the thermoelectric cooling chip 400 is turned on by the control module 500 of the thermoelectric cooling chip 400 to cool down the power element 100 to the operating temperature lower than the maximum operating temperature of the power element 100. Next, when the output torque of the motor 30 is smaller than the predetermined output torque of the motor 30, the thermoelectric cooling chip 400 is turned off by the control module 500.

According to the disclosure, the heat dissipating capability of the power heat dissipation device is influenced by the heat-conducting layer and the thermoelectric cooling chip. When the operating temperature of the power element is higher than the maximum operating temperature, the thermoelectric cooling chip is temporarily turned on to cool down the power element. When the power element is cooled down and the operating temperature of the power element is lower than the maximum operating temperature, the thermoelectric cooling chip is turned off. The timing of turning on and turning off the thermoelectric cooling chip is determined by the status of the power element so that the electric power waste of the normally functioning thermoelectric cooling chip is reduced, and the extra heat generated by the normally functioning thermoelectric cooling chip is also prevented. Therefore, it is favorable for decreasing the burden of the heat sink and avoiding the operating temperature of the power element getting higher than the maximum operating temperature of the power element. As a result, the efficiency of the power element is improved, and the power heat dissipation device provides sufficient heat dissipation capabilities when the thermoelectric cooling chips are functioning or not functioning.

In addition, the ratio of the area of the orthogonal projection of the thermoelectric cooling chip on the heat-absorbing-surface to the area of the orthogonal projection of the effective heat conducting region on the heat-absorbing-surface is between 0.15 and 0.58 so as to effectively avoid that the heat dissipation capability of the heat sink is reduced by the thermoelectric cooling chips when the thermoelectric cooling chips are turned off. Therefore, the ratio of the areas mentioned above favorably improves the heat dissipating capability of the power heat dissipation device.

What is claimed is:

1. A power heat dissipation device, comprising:
a heat-conducting layer having a heat-absorbing-surface and a heat-dissipating-surface which are opposite to each other;
a heat sink in thermal contact with the heat-dissipating-surface of the heat-conducting layer; and
at least one thermoelectric cooling chip embedded in the heat-conducting layer;
wherein, the heat-conducting layer has an effective heat-conducting-region, A1 is an area on the heat-absorbing-surface which the effective heat-conducting-region projects on, A2 is an area on the heat-absorbing-surface which the thermoelectric cooling chip projects on, and the ratio of A2 to A1 is between 0.15 and 0.58.

2. The power heat dissipation device of claim 1, wherein a number of the at least one thermoelectric cooling chip is plural, and the plurality of thermoelectric cooling chips is spaced apart from each other.

3. The power heat dissipation device of claim 1, further comprising at least one power element installed on the heat-conducting layer, the heat-absorbing-surface of the heat-conducting layer being in thermal contact with the at least one power element, and a number of the at least one power element is proportional to a number of the at least one thermoelectric cooling chip.

4. The power heat dissipation device of claim 3, wherein a part of an orthogonal projection of the at least one thermoelectric cooling chip on the heat-absorbing-surface is overlapped with an orthogonal projection of the at least one power element on the heat-absorbing-surface.

5. The power heat dissipation device of claim 3, wherein the at least one thermoelectric cooling chip and the at least one power element are in direct thermal contact with each other.

6. The power heat dissipation device of claim 3, wherein the at least one thermoelectric cooling chip is spaced apart from the at least one power element.

7. The power heat dissipation device of claim 6, wherein the at least one thermoelectric cooling chip is spaced apart from the heat-absorbing-surface and the heat-dissipating-surface of the heat-conducting layer.

8. The power heat dissipation device of claim 3, wherein the effective heat-conducting-region is a part of the heat-conducting layer with a temperature higher than 35% of a maximum operating temperature of the at least one power element.

9. The power heat dissipation device of claim 8, wherein the at least one power element has a central heat point, the central heat point is located at a center point on a surface of the effective heat-conducting-region, a width and a length of the effective heat-conducting-region are three times larger than a width and a length of the at least one power element, respectively, and a cross-sectional area of the effective heat-conducting-region is proportional to a power of the at least one power element.

10. The power heat dissipation device of claim 3, wherein the at least one power element has a heat releasing surface, the heat releasing surface is in thermal contact with the heat-absorbing-surface of the heat-conducting layer.

11. The power heat dissipation device of claim 3, wherein the at least one power element is a transistor.

12. The power heat dissipation device of claim 1, wherein the heat-conducting layer is an aluminum substrate, and the heat sink is a cooling fin set.

13. The power heat dissipation device of claim 1, wherein the at least one thermoelectric cooling chip is turned on when an output current of a motor is larger than a predetermined output current, an output torque of the motor is larger than a predetermined output torque, or an output power of the motor is larger than a predetermined output power.

14. A power heat dissipation control method, comprising:
obtaining an output current of a motor; and
turning on a thermoelectric cooling chip when the output current is larger than a predetermined output current.

15. The power heat dissipation control method of claim 14, further comprising turning off the thermoelectric cooling chip when the output current is smaller than a predetermined output current.

16. A power heat dissipation control method, comprising:
obtaining an output torque of a motor; and
turning on a thermoelectric cooling chip when the output torque is larger than a predetermined output torque.

17. The power heat dissipation control method of claim 16, further comprising turning off the thermoelectric cooling chip when the output torque is smaller than a predetermined output torque.

18. A power heat dissipation control method, comprising:
obtaining an output power of a motor; and
turning on a thermoelectric cooling chip when the output power is larger than a predetermined output power.

19. The power heat dissipation control method of claim 18, further comprising turning off the thermoelectric cooling chip when the output power is smaller than a predetermined output power.

20. The power heat dissipation control method of claim 18, wherein the step of obtaining the output power of the motor further comprises:
detecting a rotational speed and a torque of the motor; and
obtaining the output power derived from the rotational speed and the torque.
